(19) United States
(12) Patent Application Publication
(10) Pub. No.: US 2005/0252447 A1
(43) Pub. Date: Nov. 17, 2005

(54) Gas blocker plate for improved deposition

(75) Inventors: Maosheng Zhao, Santa Clara, CA (US); Juan Carlos Rocha-Alvarez, Sunnyvale, CA (US)

Correspondence Address: Patent Counsel;Applied Materials, Inc., Legal Affairs Department, M/S 3061, P.O. Box 450A, Santa Clara, CA, 95052, US

(73) Assignee: APPLIED MATERIALS, INC., Santa Clara, CA (US)

(21) Appl. No.: 10/843,839

(22) Filed: May 11, 2004

(51) Int. Cl. C23C 16/00

(52) U.S. Cl. 118/715

(57) ABSTRACT

Embodiments of the present invention are directed to a blocker for a gas distribution system for use in semiconductor deposition apparatus. The gas distribution system includes a faceplate having a plurality of faceplate apertures to distribute a gas flow onto a surface of a substrate disposed downstream of the faceplate for film deposition on the substrate; and a blocker disposed upstream of the faceplate. The blocker includes a generally planar blocker surface facing the faceplate and a side wall disposed around a periphery of the blocker surface. The blocker surface includes a plurality of blocker holes to permit gas flow therethrough to the faceplate. The side wall is disposed near an edge of the faceplate and includes a plurality of side apertures to permit gas flow therethrough to the faceplate.

### CROSS-REFERENCES TO RELATED APPLICATIONS

NOT APPLICABLE

### BACKGROUND OF THE INVENTION

This invention relates generally to semiconductor processing and, more particularly, to an improved blocker plate in a gas distribution system, for instance, for a chemical vapor deposition chamber to provide improved deposition.

One of the primary steps in the fabrication of modern semiconductor devices is the formation of a thin layer on a semiconductor substrate by chemical reaction of gases. Such a deposition process is referred to generally as chemical-vapor deposition (“CVD”). Conventional thermal CVD processes supply reactive gases to the substrate surface where heat-induced chemical reactions take place to produce a desired layer. Plasma-enhanced CVD (“PECVD”) techniques, on the other hand, promote excitation and/or dissociation of the reactant gases by the application of radio-frequency (“RF”) energy to a reaction zone near the substrate surface, thereby creating a plasma. The high reactivity of the species in the plasma reduces the energy required for a chemical reaction to take place, and thus lowers the temperature required for such CVD processes as compared to conventional thermal CVD processes.

CVD processes, such as those used in the fabrication of integrated circuits, are carried out in process chambers which typically include a gas distribution assembly through which gases are introduced into the process chamber. Gas distribution assemblies are commonly utilized in CVD chambers to uniformly distribute gases over the substrate surface upon their introduction into the chamber. Uniform gas distribution is necessary to enhance uniform deposition characteristics on the surface of a substrate positioned in the chamber for processing.

Generally, a gas distribution assembly includes a grounded gas inlet manifold connected to a gas source to provide gases to a process chamber. The gas inlet manifold inlets gases into a gas diffuser to uniformly introduce gases into the CVD chamber above a substrate surface. Referring to FIG. 1, a gas diffuser system 20 communicates directly with the CVD chamber and typically includes a gas injection cover plate 14, a blocker plate 40, and a faceplate 33 to evenly disperse gases inlet from a single gas feed line over at least the area of the substrate while nimiing turbulent gas flow. The blocker plate 40 is generally a flat, annular plate member having a plurality of very small apertures or holes passing therethrough to disperse the gas inlet therein uniformly into a space above the faceplate 33. The gas is typically inlet from a single gas line wherein the reactant and carrier gases have been mixed, thereby providing a high concentration of gas over the center of the blocker plate 40 at a localized area. The faceplate 33 is also a generally flat, annular member having a plurality of apertures or holes, larger than the apertures of the blocker plate 40, through which the gases pass or diffuse to provide a uniform concentration of gases evenly over the substrate.

The cover plate 14 defines a central gas inlet passage 19 through which gases are provided into the system 20. The faceplate 33 utilizes an o-ring seal 50 which mounts within an o-ring groove. A second o-ring seal 54 resides within an o-ring groove formed in the underside of the outer surface 48 of the faceplate 33, and the faceplate 33 is mounted within a central orifice formed through an RF isolation plate 60. The RF isolation plate 60 is formed of a non-conductor, such as a ceramic or polymer material, to isolate the RF power from the grounded base plate 12. Thereafter, utilizing another o-ring 62 which resides within an o-ring groove formed in the base plate 12, the assembled components are mounted into an octagonal recess formed within the base plate 12.

The processing chamber includes chamber walls 68 which support the gas distribution system 20 on the upper edge of the walls 68. A substrate support member 72 is disposed in the lower portion of the chamber and extends through the lower wall of the chamber to support a substrate thereon during processing. A vacuum exhaust channel 74 is disposed about the outer perimeter of the substrate support member to uniformly exhaust gases from the chamber. A cover 70 is typically disposed over the gas distribution assembly to shield the gas distribution system 20 and to prevent RF leakage.

As further shown in FIG. 1, the faceplate 33 is typically disposed below the blocker plate 40 and at least partially forms the upper boundary of the processing region 76 of the chamber. Accordingly, the gases flow through the small apertures of the blocker plate 40 and subsequently through the apertures of the faceplate 33 and into the chamber where they undergo plasma assisted chemical reactors. A substrate is positioned within the chamber on the substrate support member 72. The gas diffuser 20 is electrically biased by an RF power source 15 to generate a plasma in processing region 76. Precursor gases are inlet through the cover plate 14 and flow into the region 41 above the blocker plate 40. The gases are then dispersed above the blocker plate 40 and pass through the apertures formed in the blocker plate and into a space 78 above the faceplate 33. The gases are then further dispersed over the upper surface of the faceplate 33 and pass through the apertures formed in the faceplate to uniformly distribute the gases over the surface of the substrate where the gases react with one another and deposit on the substrate.

The approach to produce a uniform deposition of films by PECVD is by redistributing holes on the flat surface of the blocker plate. Due to the high depletion of reaction species at the edge of the faceplate and the plasma boundary limitation, a film such as the Black Diamond OMCTS (Octamethylcyclotetrasiloxane) film has an edge-thin profile that can be quite extreme, and its high nonuniformity is largely insensitive to surface hole distribution on the blocker plate. Using existing hardware, the film thickness nonuniformity is as high as 8-10% with significant edge thin profile. There is a thick white film buildup at the edge of the faceplate. It is believed that the depletion of reaction species by the edge of the faceplate and the plasma boundary limitation cause extremely low deposition on the edge of the wafer. Various existing blocker plates were tested but the high nonuniformity in film thickness was insensitive to the hole distribution on the flat surface of the blocker.

### BRIEF SUMMARY OF THE INVENTION

Embodiments of the present invention are directed to a blocker for a gas distribution system for use in semiconductor deposition apparatus. The blocker has a bottom surface with a distribution of bottom holes therethrough and a side wall along the edge of the bottom surface that also includes a plurality of side apertures to permit gas flow therethrough. The side apertures allow additional process gases to be delivered to the edge portion of the substrate to compensate for the reaction species loss along the edge portion of the substrate due to high deposition on the edge of the faceplate. In specific embodiments, the side apertures are substantially larger in size than the bottom holes.

In accordance with an aspect of the present invention, a gas distribution system comprises a faceplate having a plurality of faceplate apertures to distribute a gas flow onto a surface of a substrate disposed downstream of the faceplate for film deposition on the substrate, and a blocker disposed upstream of the faceplate. The blocker includes a generally planar blocker surface facing the faceplate and a side wall disposed around a periphery of the blocker surface. The blocker surface includes a plurality of blocker holes to permit gas flow therethrough to the faceplate. The side wall is disposed near an edge of the faceplate and includes a plurality of side apertures to permit gas flow therethrough to the faceplate.

In some embodiments, the side wall of the blocker includes a single row of side apertures distributed generally evenly around the periphery of the blocker surface. The side apertures are greater in size than the blocker holes. The side apertures are at least about twice as large in diameter as the blocker holes. The side apertures are generally uniform in size. The side apertures are oriented generally parallel to the faceplate and outwardly away from a center region of the blocker. The side wall of the blocker extends away from the faceplate. A flow diverter step is disposed around the periphery of the blocker surface and extending toward the faceplate in a direction opposite from the side wall. The flow diverter step has a generally uniform height measured from the blocker surface. The flow diverter step has a height which is smaller than a diameter of the side apertures. The blocker surface is generally parallel to the faceplate and the flow diverter step is generally perpendicular to the blocker surface. The side apertures are oriented generally perpendicular to the blocker holes.

Another aspect of the present invention is directed to a blocker for a gas distribution system to buffer a gas flow to a faceplate which includes a plurality of faceplate apertures to distribute the gas flow onto a surface of a substrate disposed downstream of the faceplate for film deposition on the substrate. The blocker comprises a generally planar blocker surface having a plurality of blocker holes to permit gas flow therethrough, and a side wall disposed around a periphery of the blocker surface. The side wall includes a plurality of side apertures to permit gas flow therethrough outwardly away from a center region of the blocker.

### BRIEF DESCRIPTION OF THE DRAWINGS

FIG. 1 is a simplified cross-sectional view of a gas distribution assembly in a CVD chamber.

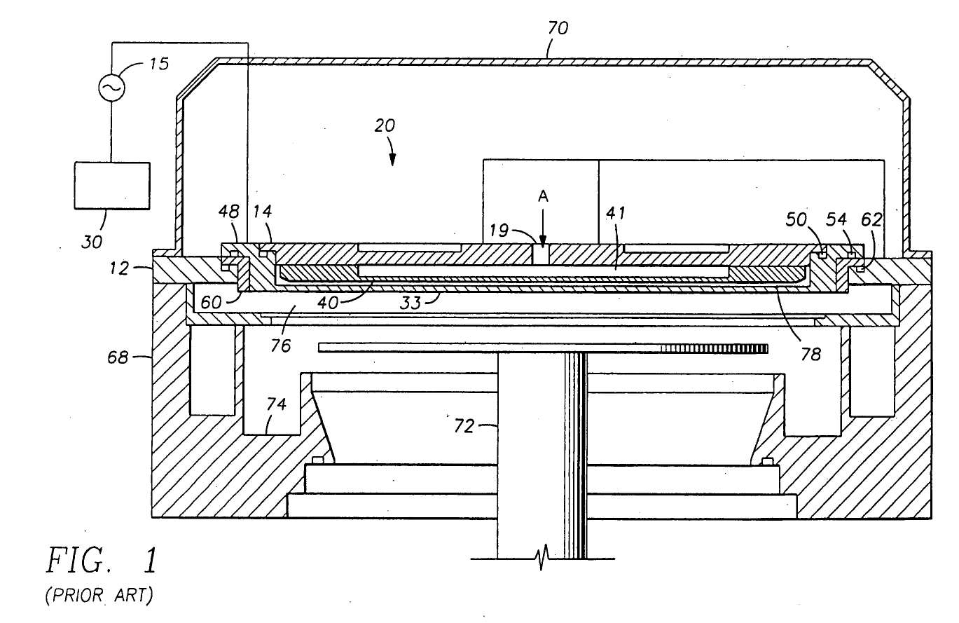

FIG. 2 is a an upper perspective view of a blocker for use in the gas distribution assembly according to an embodiment of the present invention.

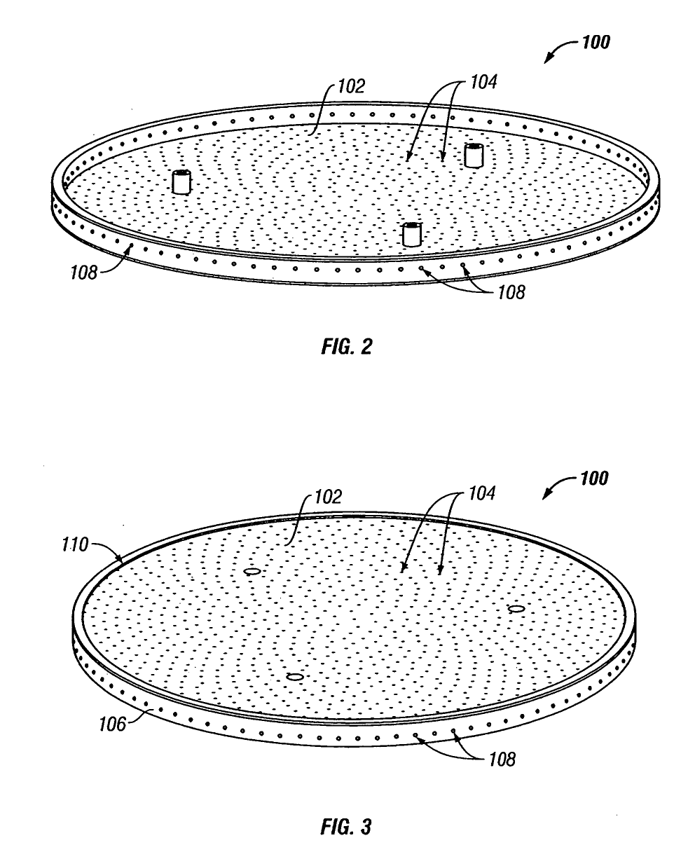

FIG. 3 is a lower perspective view of the blocker of FIG. 2.

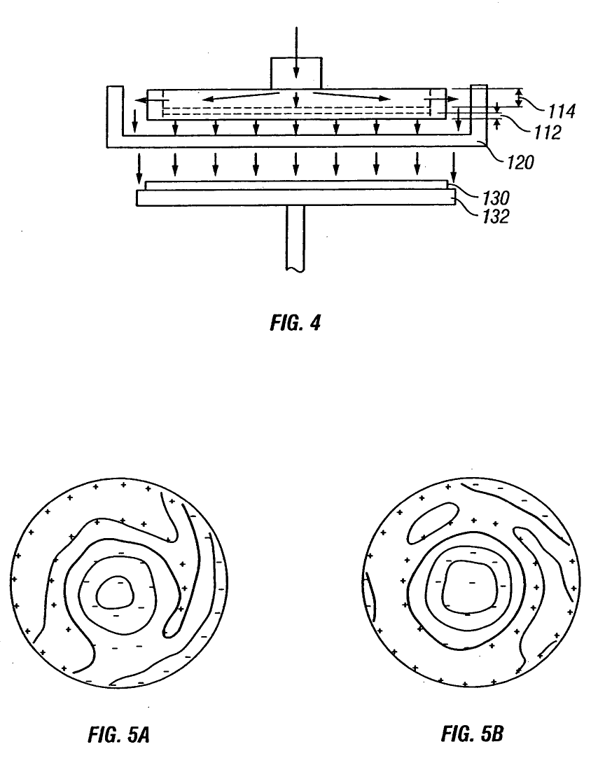

As illustrated in FIG. 4, the gas flows through the bottom holes 104 and the side apertures 108, and then through the holes in the faceplate 120 to the substrate 130 supported on a substrate support or heater-pedestal 132. The side apertures 108 produce a higher gas flow rate to the edge region of the faceplate 120 than to the center region of the faceplate 120. The flow diverter step 110 prevents or reduces the gas flow from the edge of the blocker 100 to the center region of the faceplate 120, so as to maintain a higher flow rate in the edge region than in the center region of the faceplate 120.

The number and size of side apertures 108 provide additional variables to control the gas flow to achieve a more uniform deposition. For depositing a low-K film using an organosilicon precursor such as OMCTS, the heavier molecular weight of the precursor as compared to a silicon precursor such as silane makes it more difficult to achieve a uniform deposition. The deposition rate is an inverse function of the deposition temperature. The faceplate 120 has a higher temperature in the center than in the edge region due to the exposure to the heat generated from the heater-pedestal 132 supporting the substrate 130. The difference in temperature can be about 10-20° C. As a result, there is more deposition buildup on the edge region than on the center region of the faceplate 120. This deposition buildup reduces the gas flow rate to the edge region of the substrate 130. By providing the side apertures 108 to increase the gas flow rate to the edge region of the substrate 130, the blocker 100 compensates for the flow impedance due to the deposition buildup on the edge region of the faceplate 120 to achieve a more uniform deposition on the substrate 130. The number and size of the side apertures 108 can be selected based on the process gas composition and process conditions including the heater temperature, chamber pressure, gas flow rate, and physical spacing between the faceplate and the heater-pedestal.

FIGS. 5A and 5B show thickness maps of film deposition on a pair of substrate using blockers having side apertures in a dual chamber 200-mm Producer™ apparatus available from Applied Materials, Santa Clara, Calif. The film is a low-K Black Diamond OMCTS film having a thickness of about 6.5 kÅ. The thickness variation is about 1.6% in FIG. 5A and is about 1.4% in FIG. 5B. The film is deposited from OMCTS (about 1330 mg/min) introduced with an injection valve, O₂ (about 90 sccm), and helium (about 450 sccm). The chamber pressure is about 5 torr, and the heater temperature is about 350° C. The deposition employs in-situ plasma having a plasma power of about 350 W at the high frequency of about 13.56 MHz, and a plasma power of about 100 W at the low frequency of about 350 kHz. The dielectric constant of the film is about 3.0.

A marathon run of 2000 substrates per chamber were conducted. A clean process using NF₃ with a remote plasma source was performed after every deposition. Afterwards, the chambers were inspected and found to be very clean. There was no noticeable deposition build-up inside the chamber. The side apertures 108 produce a very low pressure drop across the blocker 100, which minimizes recombination of free clean radicals and delivers more free radicals to the chamber as compared to previous blockers. Moreover, the side apertures 108 deliver more clean gas to the edge region of the faceplate 120 where more build-up is found in previous systems. The additional clean gas reduces build-up in the edge region of the faceplate 120. These factors contribute to provide a more efficient clean than that with previous blockers. Indeed, the cleaning time can be reduced from about 200 seconds to about 160 seconds, and hence less cleaning gas is required.

It is to be understood that the above description is intended to be illustrative and not restrictive. Many embodiments will be apparent to those of skill in the art upon reviewing the above description. For example, the blocker may be used for other types of deposition processes. The number and size of the side apertures on the blocker provide additional variables to tune the deposition to achieve improved uniformity. The scope of the invention should, therefore, be determined not with reference to the above description, but instead should be determined with reference to the appended claims along with their full scope of equivalents.

1. A gas distribution system comprising:
a faceplate having a plurality of faceplate apertures to distribute a gas flow onto a surface of a substrate disposed downstream of the faceplate for film deposition on the substrate; and
a blocker disposed upstream of the faceplate, the blocker including a generally planar blocker surface facing the faceplate and a side wall disposed around a periphery of the blocker surface, the blocker surface including a plurality of blocker holes to permit gas flow therethrough to the faceplate, the side wall being disposed near an edge of the faceplate and including a plurality of side apertures to permit gas flow therethrough to the faceplate.

2. The system of claim 1 wherein the side wall of the blocker includes a single row of side apertures distributed generally evenly around the periphery of the blocker surface.

3. The system of claim 1 wherein the side apertures are greater in size than the blocker holes.

4. The system of claim 3 wherein the side apertures are at least about twice as large in diameter as the blocker holes.

5. The system of claim 1 wherein the side apertures are generally uniform in size.

6. The system of claim 1 wherein the side apertures are oriented generally parallel to the faceplate and outwardly away from a center region of the blocker.

7. The system of claim 1 wherein the side wall of the blocker extends away from the faceplate.

8. The system of claim 7 further comprising a flow diverter step disposed around the periphery of the blocker surface and extending toward the faceplate in a direction opposite from the side wall.

9. The system of claim 8 wherein the flow diverter step has a generally uniform height measured from the blocker surface.

10. The system of claim 9 wherein the flow diverter step has a height which is smaller than a diameter of the side apertures.

11. The system of claim 8 wherein the blocker surface is generally parallel to the faceplate and the flow diverter step is generally perpendicular to the blocker surface.

12. The system of claim 1 wherein the side apertures are oriented generally perpendicular to the blocker holes.

13. A blocker for a gas distribution system to buffer a gas flow to a faceplate which includes a plurality of faceplate apertures to distribute the gas flow onto a surface of a substrate disposed downstream of the faceplate for film deposition on the substrate, the blocker comprising:
a generally planar blocker surface having a plurality of blocker holes to permit gas flow therethrough; and
a side wall disposed around a periphery of the blocker surface, the side wall including a plurality of side apertures to permit gas flow therethrough outwardly away from a center region of the blocker.

14. The blocker of claim 13 wherein the side wall of the blocker includes a single row of side apertures distributed generally evenly around the periphery of the blocker surface.

15. The blocker of claim 13 wherein the side apertures are greater in size than the blocker holes.

16. The blocker of claim 13 wherein the side apertures are generally uniform in size.

17. The blocker of claim 13 further comprising a flow diverter step disposed around the periphery of the blocker surface and extending in a direction opposite from the side wall.

18. The blocker of claim 17 wherein the flow diverter step has a generally uniform height measured from the blocker surface.

19. The blocker of claim 18 wherein the flow diverter step has a height which is smaller than a diameter of the side apertures.

20. The blocker of claim 13 wherein the side apertures are oriented generally perpendicular to the blocker holes.
